(19) United States
(12) Patent Application Publication
(10) Pub. No.: US 2026/0040509 A1
(43) Pub. Date: Feb. 5, 2026

(54) ELECTRIC POWER CONVERSION DEVICE

(71) Applicants: HYUNDAI MOTOR COMPANY, SEOUL (KR); KIA CORPORATION, SEOUL (KR)

(72) Inventor: Yun Ho Kim, Hwaseong-si (KR)

(73) Assignees: HYUNDAI MOTOR COMPANY, SEOUL (KR); KIA CORPORATION, SEOUL (KR)

(21) Appl. No.: 19/225,620

(22) Filed: Jun. 2, 2025

(30) Foreign Application Priority Data
Jul. 30, 2024 (KR) 10-2024-0101046

(51) Int. Cl. H05K 7/20

(52) U.S. Cl. CPC H05K 7/20927

(57) ABSTRACT

Disclosed is an electric power conversion device including a plurality of power modules stacked in one direction, and a plurality of cooling channels disposed between or outside the power modules such that at least one surface of each of the plurality of cooling channels is in contact with one surface or a remaining surface of one of the power modules, wherein a cooling medium from outside is introduced into internal cooling channels disposed between the power modules, and the cooling medium discharged from the internal cooling channels is introduced into outermost cooling channels disposed outside the power modules.

### CROSS-REFERENCE TO THE RELATED APPLICATION

This application claims priority from Korean Patent Application No. 10-2024-0101046, filed on Jul. 30, 2024, in the Korean Intellectual Property Office, the disclosure of which is incorporated herein by reference in its entirety.

### TECHNICAL FIELD

The present disclosure relates to an electric power conversion device.

### BACKGROUND

A power module is an electronic device used to control and convert electric power, and mainly adjusts or converts voltage, current, or power. For example, power modules are used in devices, such as DC-DC converters, AC-DC converters, and inverters, to enable (e.g., efficient) energy conversion and power management.

Meanwhile, in relation to electric vehicles, demand for electric power conversion devices with high output and high efficiency to increase a driving range is increasing.

The matters described in this Background section are (e.g., only) for enhancement of understanding of the background of the disclosure, and should not be taken as acknowledgement that they correspond to prior art already known to those skilled in the art.

### SUMMARY

Power modules generate heat depending on use of an electric power conversion device. Switching elements in the power modules have impacted (e.g., reduced) durability or are damaged when the temperature in the power modules exceeds a designated temperature, and therefore, cooling channels configured to cool the power modules are provided. In order to achieve a high-power and high-efficiency power conversion device, the maximum current may be (e.g., must be) increased, and power modules that may withstand high current and a cooling system configured to cool the power modules may be used (e.g., are required).

Therefore, the present disclosure has been made in view of the above problems, and it is an object of the present disclosure to provide a structure of cooling channels that uses a stack structure in which power modules are disposed in a plurality of layers to provide a high-power and high-efficiency power conversion device, and may (e.g., effectively) cool the power modules.

Technical problems to be achieved in the present disclosure are not limited to the technical problems mentioned above, other technical problems not mentioned may be clearly understood by those skilled in the art to which the present disclosure pertains from the following description.

In accordance with an aspect of the present disclosure, the above and other objects can be accomplished by the provision of an electric power conversion device including a plurality of power modules stacked in one direction, and a plurality of cooling channels disposed between or outside the power modules such that at least one surface of (e.g., each of) the plurality of cooling channels is in contact with one surface or a remaining surface of one of the power modules, wherein a cooling medium from outside is introduced into internal cooling channels disposed between the power modules, and the cooling medium discharged from the internal cooling channels is introduced into outermost cooling channels disposed outside the power modules.

A direction of a flow of the cooling medium in the internal cooling channels and a direction of a flow of the cooling medium in the outermost cooling channels may be opposite to each other.

A first inlet configured such that the cooling medium is introduced therethrough may be formed at one end (e.g., of each) of the internal cooling channels, and a first outlet configured such that the introduced cooling medium is discharged to an adjacent one of the outermost cooling channels therethrough may be formed at a remaining end (e.g., of each) of the internal cooling channels.

A second outlet configured such that the introduced cooling medium is discharged outside therethrough may be formed at one end (e.g., of each) of the outermost cooling channels.

An exhaust passage configured such that the cooling medium discharged from the second outlets of the outermost cooling channels flows therethrough may be formed at one end of (e.g., each) of the internal cooling channels.

The outermost cooling channels may be provided in a pair, and a cooling medium inlet configured such that the cooling medium from outside is introduced therethrough and a cooling medium outlet configured such that the cooling medium discharged from the outermost cooling channels is discharged outside therethrough may be formed at the outermost cooling channels.

The cooling medium from outside may be introduced through the cooling medium inlet formed at one of the outermost cooling channels, and may flow into the internal cooling channels.

The cooling medium discharged from the outermost cooling channels may be discharged outside through the cooling medium outlet formed at a remaining one of the outermost cooling channels.

The power modules may be stacked in three layers, the internal cooling channels may be provided in a pair and disposed between the power modules, and the outermost cooling channels may be provided in a pair and disposed outside the power modules disposed in outermost areas.

A cooling medium inlet configured such that the cooling medium from outside is introduced therethrough and a cooling medium outlet configured such that the cooling medium discharged from the outermost cooling channels is discharged outside therethrough may be formed at the outermost cooling channels.

The cooling medium introduced through the cooling medium inlet may branch through first inlets, each of the first inlets formed at one end (e.g., of each) of the internal cooling channels, may be introduced into the internal cooling channels, and may be introduced into the outermost cooling channels through first outlets of the internal cooling channels.

The cooling medium introduced into the outermost cooling channels may be discharged outside through second outlets and flow through exhaust passages, each formed at one end (e.g., of each) of the internal cooling channels, and the cooling medium discharged from (e.g., each of) the outermost cooling channels may be combined and discharged outside through the cooling medium outlet.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a view illustrating a situation in which thermal overlap occurs due to stacking of power modules;

FIG. 2 is a view illustrating an electric power conversion device according to one embodiment of the present disclosure;

FIG. 3 is an exploded perspective view of the electric power conversion device according to one embodiment of the present disclosure;

FIG. 4 is a view schematically illustrating the flow of a cooling medium flowing through cooling channels; and

FIGS. 5 and 6 are views illustrating internal cross-sections of the cooling channels.

### DETAILED DESCRIPTION

In the following description of embodiments disclosed in the present disclosure, a detailed description of known functions and configurations incorporated herein will be omitted when it may make the subject matter of the present disclosure rather unclear. In addition, the accompanying drawings are (e.g., only) for easy understanding of the embodiments of the present disclosure, and the technical idea disclosed in the present disclosure is not limited by the accompanying drawings and may (e.g., should) be understood to include (e.g., all) changes, equivalents or substitutes included in the spirit and technical scope of the present disclosure.

In the following description of the embodiments, terms, such as “first” and “second”, may be used to describe various elements but do not limit the elements. These terms are used (e.g., only) to distinguish one element from other elements.

Singular expressions may encompass plural expressions, unless they have clearly different contextual meanings.

In the following description of the embodiments, terms, such as “including”, “comprising” and “having”, are to be interpreted as indicating the presence of characteristics, numbers, steps, operations, elements or parts stated in the description or combinations thereof, and do not exclude the presence of one or more other characteristics, numbers, steps, operations, elements, parts or combinations thereof, or possibility of adding the same.

The suffixes “module” and “part” for components used in the following description are given or used interchangeably (e.g., only) for ease of preparing the description of the present disclosure, and do not have distinct meanings or roles in themselves.

When an element or layer is referred to as being “connected to” or “coupled to” another element or layer, it may be directly connected to or coupled to the other element or layer, or intervening elements or layers may be present. In contrast, when an element is referred to as being “directly connected to” or “directly coupled to” another element or layer, there may be no intervening elements or layers present.

Hereinafter, embodiments disclosed in the present disclosure will be described in detail with reference to the accompanying drawings, the same or similar elements will be denoted by the same reference numerals even though they are depicted in different drawings, and a redundant description of these elements will be omitted.

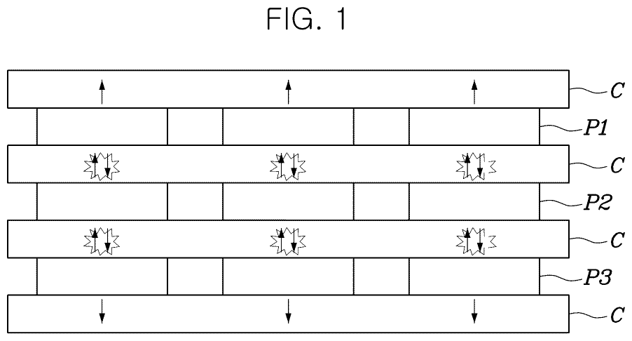

FIG. 1 is a view illustrating a situation in which thermal overlap occurs due to stacking of power modules. Referring to FIG. 1, when three or more power modules P1, P2, and P3 are stacked, a power module P2 is (e.g., inevitably) placed between other power modules Pl and P3. Thermal overlap occurs in the power module P2 placed between the other power modules Pl and P3, as shown in this figure. As such, in a structure in which power modules are stacked, heat generated from other power modules may be transferred to a power module located between the other power modules, and may result in a decrease in durability of the power module due to a decrease in cooling performance, or failure of the power module.

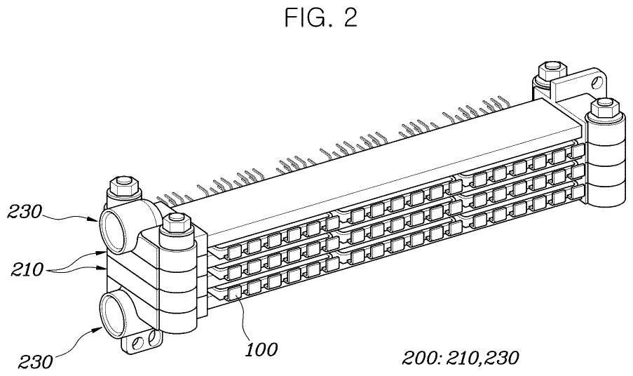

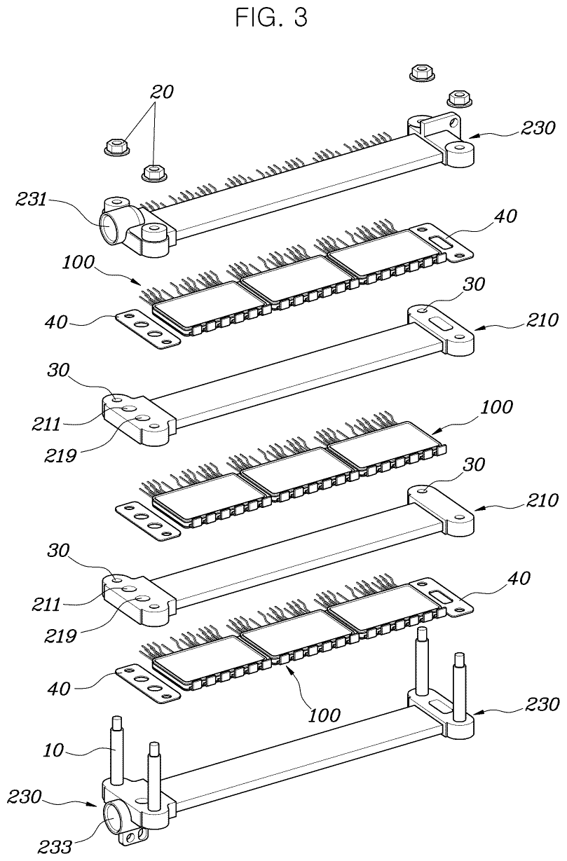

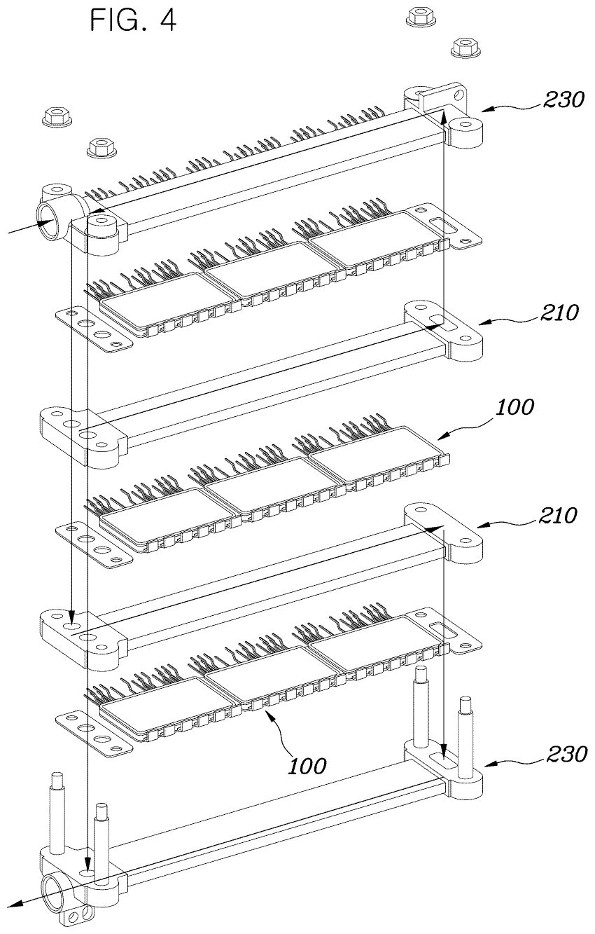

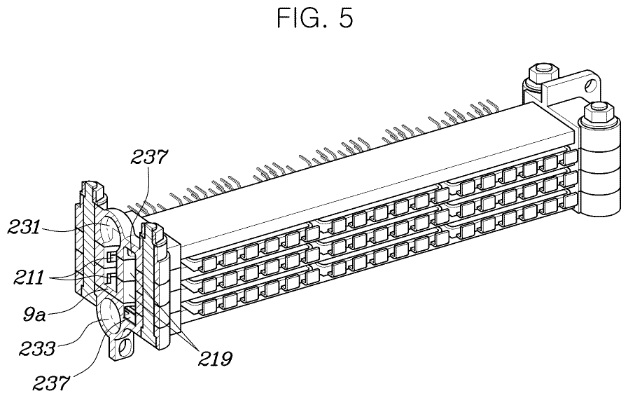

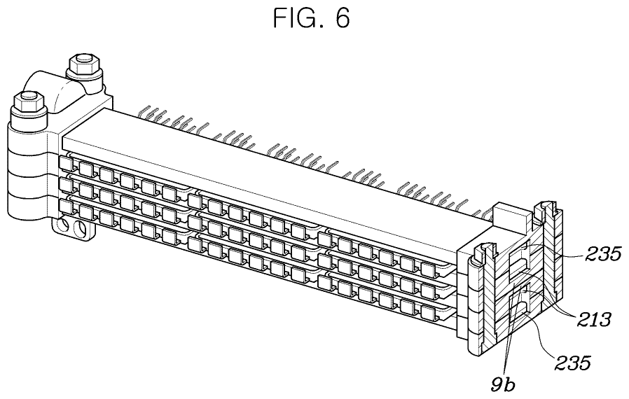

FIG. 2 is a view illustrating an electric power conversion device according to one embodiment of the present disclosure, and FIG. 3 is an exploded perspective view of the electric power conversion device according to one embodiment of the present disclosure. FIG. 4 is a view schematically illustrating the flow of a cooling medium flowing through cooling channels. FIGS. 5 and 6 are views illustrating internal cross-sections of the cooling channels. The present disclosure will be described with reference to FIGS. 2 to 6.

The electric power conversion device according to the present disclosure includes a plurality of power modules including switching elements and stacked in one direction, and a plurality of cooling channels 200 configured to cool the power modules 100. Although the power modules 100 are shown as being stacked in the vertical direction in the drawings, the power modules 100 may be stacked in the horizontal direction.

As shown in the drawings, the power modules 100 are stacked in three layers. However, this is according to one embodiment, the number of stacked layers of the power modules 100 may exceed three. However, since at least one power module is placed between other power modules (e.g., only) when three or more power modules are stacked, a structure in which power modules are stacked in three layers may be (e.g., is) the most representative embodiment.

For convenience of explanation, the structure in which power modules are stacked in three layers is assumed, but the number of stacked layers of power modules may be different (e.g., is not important).

Referring to FIGS. 2 and 3, the plurality of cooling channels 200 is disposed between or outside the power modules 100 such that at least one surface (e.g., of each) of the plurality of cooling channels 200 is in contact with a (e.g., one) surface or the other surface of one of the power modules 100. Specifically, the plurality of cooling channels 200 includes internal cooling channels 210 disposed between the power modules 100, and outermost cooling channels 230 disposed outside the power modules 100.

Accordingly, both sides of the internal cooling channels 210 are in contact with the power modules 100, and the internal cooling channels 210 exchange heat with (e.g., all) the power modules 100 located on both sides thereof. In addition, since the outermost cooling channels 230 are disposed on the outermost areas, the outermost cooling channels 230 exchange heat with the power modules 100 in the state in which a (e.g., only) (e.g., one) surface (e.g., of each) of the outermost cooling channels 230 is in contact with the power module 100. Therefore, in this structure, the cooling performance of the internal cooling channels 210 may be preferred (e.g., is of greater importance) than that of the outermost cooling channels 230.

According to one embodiment of the present disclosure, the power modules 100 are stacked in three layers, the internal cooling channels 210 are disposed between the respective power modules 100, and a total of a pair of internal cooling channels 210 is provided. Further, a pair of outermost cooling channels 230 is provided, and is disposed outside the power modules 100 disposed in the outermost areas.

As shown in FIG. 3, a pair of outermost cooling channels 230 and a pair of internal cooling channels 210 are fastened with studs 10 and nuts 20. The respective cooling channels 200 are fastened with the studs 10 and the nuts 20, thereby providing (e.g., fixing) force to the power modules 100 disposed between the cooling channels 200. Further, since the cooling channels 200 are configured in a fastening manner, it may be easier (e.g., is easy) to repair or replace the cooling channels 200 in the event of failure in the future, and it may be easier (e.g., is easy) to change the design in the future even if the number of the stacked power modules 100 or the cooling channels 200 is increased or decreased. Of course, the respective cooling channels 200 may be assembled through a clamping method or various other mechanical fastening methods in addition to using the studs 10 and the nuts 20, may be coupled through material methods, such as using an adhesive, and may also be fixed by welding or the like.

Through holes 30 through which the studs 10 pass may be formed at a plurality of points of the cooling channels 200, and the cooling channels 200 may be (e.g., sequentially) stacked through the studs 10. Here, gaskets 40 configured to prevent inflow of a cooling medium into the power modules 100 may be provided between the cooling channels 200. A point to note in the mechanical fastening methods is that, if fastening force changes due to a mechanical defect, cooling medium leakage may occur. Particularly, in the case of the power modules 100, problems, such as short circuit, may occur due to leakage of the cooling medium, and the degree of thermal expansion of the studs 10 and the nuts 20 changes due to changes in the temperature of the cooling medium or the temperature of the power modules 100, and the gaskets 40 are (e.g., required to) minimize or (e.g., substantially) prevent the cooling medium leakage due to the above problems. The gaskets 40 are provided between the respective cooling channels 200, as shown in the drawings, to perform sealing and prevent a gap between the cooling channels 200 from widening. That is, if the studs 10 and the nuts 20 are fastened with a (e.g., certain) amount of pre-load, the gaskets 40 are assembled in a slightly compressed state in the initial fastening state, and thus, the gaskets 40 may perform sealing reliably even when the studs 10 and the nuts 20 thermally expand and contract.

FIG. 4 schematically illustrates the flow of the cooling medium flowing through the cooling channels. Referring to FIGS. 3 and 4, a cooling medium inlet 231 and a cooling medium outlet 233 may be formed at one end of a pair of outermost cooling channels 230. The cooling medium inlet 231 is a portion through which the cooling medium from outside is introduced, and the cooling medium outlet 233 is a portion through which the cooling medium heated by cooling the power modules 100 is discharged to the outside again.

Here, the cooling medium may be a coolant that exchanges heat with a heat exchanger, such as a radiator or a chiller. That is, the cooling medium heated by cooling the power modules 100 may be cooled by exchanging heat with the radiator or the chiller, and may then flow back into the cooling medium inlet 231 to cool the power modules 100. Otherwise, the coolant that is expanded or the coolant just before expansion may directly flow through the cooling channels 200 to cool the power modules 100.

Referring to FIG. 5, the cooling medium introduced through the cooling medium inlet 231 flows into a pair of internal cooling channels 210. Here, a first inlet 211 is formed at one end (e.g., of each) of the internal cooling channels 210 to allow the cooling medium to be introduced therethrough, and the introduced cooling medium cools the power modules 100. At this time, the power module 100 located between the internal cooling channels 210 is intensively cooled. The cooling medium inlet 231 of the outermost cooling channel 230 and the first inlets 211 of the internal cooling channels 210 are connected to each other, and the cooling medium introduced into the cooling medium inlet 231 branches and flows into a pair of internal cooling channels 210. At this time, since the lower surface of (e.g., one of) the internal cooling channels 210 is blocked by a wall 9a, the first inlets 211 and the cooling medium outlet 233 are not connected to each other.

Referring to FIG. 6, a first outlet 213 from which the cooling medium is discharged to the adjacent outermost cooling channel 230 is formed at the other end of (e.g., each of) the internal cooling channels 210. The cooling medium discharged through the first outlets 213 is introduced into the outermost cooling channels 230 through second inlets 235 formed at the other ends of the outermost cooling channels 230, thereby cooling the adjacent power modules 100. Here, walls 9b are formed adjacent to a pair of first outlets 213, and the first outlets 213 are not connected to each other. Accordingly, the cooling medium discharged from the first outlets 213 is introduced into the adjacent outermost cooling channels 230.

Therefore, the direction of the flow of the cooling medium in the internal cooling channels 210 and the direction of the flow of the cooling medium in the outermost cooling channels 230 are opposite to each other, and the cooling medium in the outermost cooling channels 230 flows back in the direction from which the cooling medium was introduced.

Referring to FIG. 5, a second outlet 237 is formed at (e.g., one) end (e.g., of each) of the outermost cooling channels 230, and the cooling medium that has completed cooling of the power modules 100 is discharged to the outside through the second outlets 237 of the outermost cooling channels 230. The second outlets 237 are formed in both of a pair of outermost cooling channels 230. However, the cooling medium discharged from the outermost cooling channel 230 provided with the cooling medium inlet 231 flows to the second outlet 27 of the outermost cooling channel 230 provided with the cooling medium outlet 233, joins with the cooling medium branching from the cooling medium outlet 233, and is then discharged to the outside.

In order to allow the cooling medium to flow from the outermost cooling channel 230 provided with the cooling medium inlet 231 to the outermost cooling channel 230 provided with the cooling medium outlet 233, an exhaust passage 219 may be formed at (e.g., one) end (e.g., of each) of the internal cooling channels 210. The exhaust passages 219 of the internal cooling channels 210 serve as passages through which the cooling medium discharged from the second outlets 237 flows. The second outlets 237 of the pair of outermost cooling channels 230 may be connected to each other by the exhaust passages 219.

Referring again to FIG. 4, the cooling medium is introduced into the pair of internal cooling channels 310 through the cooling medium inlet 231 formed at (e.g., one) end (e.g., of one) of the pair of outermost cooling channels 230. The cooling medium introduced into the internal cooling channels 310 may cool the power module 100 located between the pair of internal cooling channels 210. The cooling medium is first introduced into the internal cooling channels 210, and may thus initially cool the power module 100 in which thermal overlap may occur so that thermal equilibrium with other power modules 100 may be achieved, thereby enabling uniform performance.

The cooling medium that has passed through the internal cooling channels 210 is bypassed and introduced into the outermost cooling channels 230 through the second inlets 235. The cooling medium introduced into the outermost cooling channels 230 intensively cools the power modules 100 disposed in the outermost areas. Since the degree of thermal overlap of the power modules 100 disposed in the outermost areas is smaller than that of the power module 100 disposed between the internal cooling channels 210, even if the power module 100 disposed between the internal cooling channels 210 is first cooled by the cooling medium, the power modules 100 disposed in the outermost areas may secure (e.g., sufficient) cooling performance.

The cooling medium discharged from the second outlets 237 of the outermost cooling channels 230 is combined in the outermost cooling channel 230 provided with the cooling medium outlet 233 and is discharged to the outside, and then, the discharged cooling medium is cooled by the radiator or the chiller. In addition, in order to (e.g., continuously) cool the power modules 100, the cooling medium may be circulated into the cooling medium inlet 231 of the outermost cooling channel 230.

From the above description, an electric power conversion device according to the present disclosure may (e.g., effectively) cool a power module in which thermal overlap occurs. Accordingly, a high-efficiency and a high-output electric power conversion device without performance deterioration of power modules may be provided.

Effects obtained by the present disclosure are not limited to the effects mentioned above, and other effects not mentioned may be clearly understood by those skilled in the art to which the present disclosure pertains from the above description.

While the present disclosure has been explained in relation to specific embodiments, it is to be understood that various modifications and changes thereof will become apparent to those skilled in the art without departing from the technical spirit of the present disclosure as provided by the appended claims.

What is claimed is:

1. An electric power conversion device comprising:
a plurality of power modules stacked in one direction; and
a plurality of cooling channels disposed between or outside the power modules such that at least one surface of each of the plurality of cooling channels is in contact with one surface or a remaining surface of one of the power modules,
wherein a cooling medium from outside is introduced into internal cooling channels disposed between the power modules, and the cooling medium discharged from the internal cooling channels is introduced into outermost cooling channels disposed outside the power modules.

2. The electric power conversion device of claim 1, wherein a direction of a flow of the cooling medium in the internal cooling channels and a direction of a flow of the cooling medium in the outermost cooling channels are opposite to each other.

3. The electric power conversion device of claim 1, wherein a first inlet configured such that the cooling medium is introduced therethrough is formed at one end of each of the internal cooling channels, and a first outlet configured such that the introduced cooling medium is discharged to an adjacent one of the outermost cooling channels therethrough is formed at a remaining end of each of the internal cooling channels.

4. The electric power conversion device of claim 3, wherein a second outlet configured such that the introduced cooling medium is discharged outside therethrough is formed at one end of each of the outermost cooling channels.

5. The electric power conversion device of claim 4, wherein an exhaust passage configured such that the cooling medium discharged from the second outlets of the outermost cooling channels flows therethrough is formed at one end of each of the internal cooling channels.

6. The electric power conversion device of claim 1, wherein the outermost cooling channels are provided in a pair,
wherein a cooling medium inlet configured such that the cooling medium from outside is introduced therethrough or a cooling medium outlet configured such that the cooling medium discharged from the outermost cooling channels is discharged outside therethrough are formed at the outermost cooling channels.

7. The electric power conversion device of claim 6, wherein the cooling medium from outside is introduced through the cooling medium inlet formed at one of the outermost cooling channels, and flows into the internal cooling channels.

8. The electric power conversion device of claim 7, wherein the cooling medium discharged from the outermost cooling channels is discharged outside through the cooling medium outlet formed at a remaining one of the outermost cooling channels.

9. The electric power conversion device of claim 1, wherein:
the power modules are stacked in three layers;
the internal cooling channels are provided in a pair and disposed between the power modules; and
the outermost cooling channels are provided in a pair and disposed outside the power modules disposed in outermost areas.

10. The electric power conversion device of claim 9, wherein a cooling medium inlet configured such that the cooling medium from outside is introduced therethrough or a cooling medium outlet configured such that the cooling medium discharged from the outermost cooling channels is discharged outside therethrough are formed at the outermost cooling channels.

11. The electric power conversion device of claim 10, wherein the cooling medium introduced through the cooling medium inlet branches through first inlets, each formed at one end of each of the internal cooling channels, is introduced into the internal cooling channels, and is introduced into the outermost cooling channels through first outlets of the internal cooling channels.

12. The electric power conversion device of claim 11, wherein the cooling medium introduced into the outermost cooling channels is discharged outside through second outlets and flows through exhaust passages, each formed at one end of each of the internal cooling channels, and the cooling medium discharged from each of the outermost cooling channels is combined and discharged outside through the cooling medium outlet.
